(19) United States
(12) Patent Application Publication
(10) Pub. No.: US 2025/0016508 A1
(43) Pub. Date: Jan. 9, 2025

(54) MEMS MICROPHONE

(71) Applicant: AAC ACOUSTIC TECHNOLOGIES (SHENZHEN) CO., LTD., Shenzhen (CN)

(72) Inventors: Xingfu Chen, Shenzhen (CN); Tangyu Zhang, Shenzhen (CN)

(21) Appl. No.: 18/399,779

(22) Filed: Dec. 29, 2023

(30) Foreign Application Priority Data
Jul. 7, 2023 (CN) 202321788695.5

(51) Int. Cl. H04R 19/04; B81B 7/00; H04R 1/04; H04R 3/00

(52) U.S. Cl. CPC H04R 19/04; B81B 7/0061; H04R 1/04; H04R 3/00; B81B 2201/0257; B81B 2203/0127; B81B 2207/012; H04R 2201/003

(57) ABSTRACT

A MEMS microphone includes substrate, housing, MEMS chip and ASIC chip. The substrate is provided with sound inlet channel communicating the receiving space with the outside. The MEMS chip includes diaphragm located on sound inlet path of sound inlet channel. The sound inlet channel includes buffering cavity, first sound inlet hole, and second sound inlet hole provided in the substrate and communicating the buffering cavity with the back cavity. The second sound inlet hole includes at least two sub-holes spaced apart from each other. When external air pressure enters the sound inlet channel, the air pressure entering from the first sound inlet hole may not directly act on the diaphragm through the second sound inlet hole, and the sub-holes can further block the airflow, which can effectively buffer the impact of the air pressure on the diaphragm, reduce diaphragm rupture, and improve reliability and performance of the MEMS microphone.

### TECHNICAL FIELD

The present disclosure relates to the field of acoustoelectric conversion technologies, and in particular, to a micro-electro-mechanical system (MEMS) microphone.

### BACKGROUND

MEMS sensors are results based on development of MEMS technologies and have a wide range of applications, such as MEMS microphones. Compared with other types of sensing devices, the MEMS sensors have advantages such as a small size and a good frequency response characteristic.

In the related art, a MEMS chip of a MEMS microphone is directly aligned with a sound hole, and atmospheric pressure may directly act on a diaphragm of the MEMS chip through the sound hole, which is prone to rupture of the diaphragm.

### SUMMARY

An objective of the present disclosure is to provide a MEMS microphone, which can effectively buffer the impact of the air pressure on the diaphragm, reduce diaphragm rupture, and improve reliability of the MEMS microphone.

The technical solution of the present disclosure is as follows. A MEMS microphone is provided. The MEMS microphone includes a substrate, a housing enclosing a receiving space together with the substrate, a MEMS chip enclosing a back cavity together with the substrate, and an application specific integrated circuit (ASIC) chip fixed to the substrate. The substrate is provided with a sound inlet channel communicating the receiving space and the outside. The MEMS chip includes a diaphragm located on a sound inlet path of the sound inlet channel. The sound inlet channel includes a buffering cavity located in the substrate, a first sound inlet hole provided in the substrate and communicating the buffering cavity with the outside, and a second sound inlet hole provided in the substrate and communicating the buffering cavity with the back cavity. The second sound inlet hole includes at least two sub-holes spaced apart from each other.

Further, in a thickness direction of the substrate, the orthographic projections of the first sound inlet hole and the second sound inlet hole do not overlap with each other.

Further, in the thickness direction of the substrate, the orthographic projection of the first sound inlet hole is located outside the back cavity.

Further, in the thickness direction of the substrate, the orthographic projection of the first sound inlet hole is located in the back cavity.

Further, in the thickness direction of the substrate, the orthographic projections of the sub-holes surrounds an outer periphery of the first sound inlet hole.

Further, a sum of cross-sectional areas of the sub-holes is smaller than 30% of a cross-sectional area of the first sound inlet hole.

Further, the substrate includes a first substrate enclosing the receiving space together with the housing and a second substrate fixed to a side of the first substrate away from the housing, the first substrate and the second substrate being spaced apart to form the buffering cavity, the first sound inlet hole is provided in the second substrate, and the second sound inlet hole is provided in the first substrate.

Further, the substrate further includes a fixing member fixed between the first substrate and the second substrate, and the first substrate, the second substrate, and the fixing member jointly enclose the buffering cavity.

Further, the buffering cavity faces the receiving space, and a junction between the housing and the first substrate faces the fixing member.

The present disclosure has the following beneficial effects.

In the solution, since the sound inlet channel includes the buffering cavity, the first sound inlet hole, and the second sound inlet hole, the second sound inlet hole includes the at least two sub-holes spaced apart from each other, and the sub-holes are micro holes, external air pressure, when entering the sound inlet channel, first passes through the first sound inlet hole, then passes through the buffering cavity for buffering, and finally acts on the diaphragm of the MEMS chip through the second sound inlet hole. In this process, the air pressure, after entering from the first sound inlet hole, may not directly act on the diaphragm through the second sound inlet hole, and the second sound inlet hole is arranged in the form of a plurality of sub-holes to further buffer the air pressure, which can effectively buffer the impact of the air pressure on the diaphragm, reduce diaphragm rupture, and improve reliability and performance of the MEMS microphone.

### BRIEF DESCRIPTION OF DRAWINGS

FIG. 1 is a schematic diagram of a sectional structure of a MEMS microphone according to a first embodiment of the present disclosure; and

FIG. 2 is a schematic diagram of a sectional structure of a MEMS microphone according to a second embodiment of the present disclosure.

### DESCRIPTION OF EMBODIMENTS

The present disclosure is further described below with reference to the accompanying drawings and embodiments.

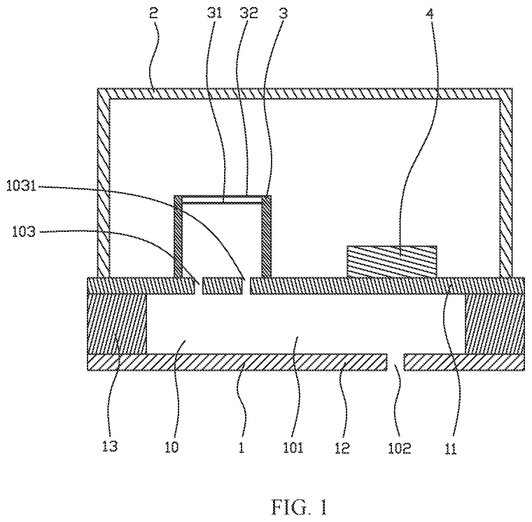

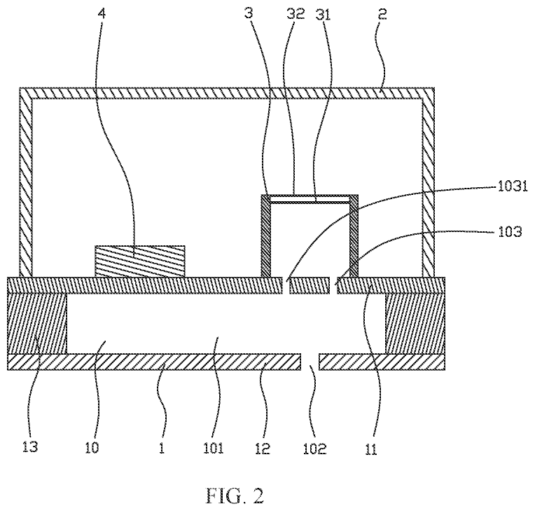

Referring to FIG. 1 to FIG. 2, a MEMS microphone is provided. The MEMS microphone includes a substrate 1, a housing 2 enclosing a receiving space together with the substrate 1, a MEMS chip 3 enclosing a back cavity together with the substrate 1, and an ASIC chip 4 fixed to the substrate 1. The substrate 1 is provided with a sound inlet channel 10 communicating the receiving space with the outside. The MEMS chip 3 has a diaphragm 31 located on a sound inlet path of the sound inlet channel 10. The sound inlet channel 10 includes a buffering cavity 101 located in the substrate 1, a first sound inlet hole 102 provided in the substrate 1 and communicating the buffering cavity 101 with the outside, and a second sound inlet hole 103 provided in the substrate 1 and communicating the buffering cavity 101 with the back cavity. The second sound inlet hole 103 faces the diaphragm 31. The second sound inlet hole 103 includes at least two sub-holes 1031 spaced apart from each other.

In the solution, since the sound inlet channel 10 includes the buffering cavity 101, the first sound inlet hole 102, and the second sound inlet hole 103, the second sound inlet hole 103 includes the at least two sub-holes 1031 spaced apart from each other, and the sub-holes 1031 are micro holes, external air pressure, when entering the sound inlet channel 10, first passes through the first sound inlet hole 102, then passes through the buffering cavity 101 for buffering, and finally acts on the diaphragm 31 of the MEMS chip 3 through the second sound inlet hole 103. In this process, the air pressure, after entering from the first sound inlet hole 102, may not directly act on the diaphragm 31 through the second sound inlet hole 103, and the second sound inlet hole 103 is arranged in the form of a plurality of sub-holes 1031 to further buffer the air pressure, which can effectively buffer the impact of the air pressure on the diaphragm 31, reduce diaphragm rupture, and improve reliability and performance of the MEMS microphone.

The MEMS chip 3 further includes a backplate 32 spaced apart from the diaphragm 31. In the solution, a solution in which the backplate 32 is located on a side of the diaphragm 31 away from the substrate 1 is shown. It should be understood that, in some embodiments, the backplate 32 may alternatively be arranged on a side of the diaphragm 31 close to the substrate 1.

Further, a sum of cross-sectional areas of the sub-holes 1031 is smaller than 30% of a cross-sectional area of the first sound inlet hole 102. In this way, the second sound inlet hole 103 formed by the sub-holes 1031 has large air resistance, and it is not easy for an airflow impulse force to be transferred to the back cavity through the second sound inlet hole 103 and further act on the diaphragm 31, thereby further improving protection for the diaphragm 31. Optionally, the sub-holes 1031 are equal in size and evenly arranged. The second sound inlet hole 103 is formed by a plurality of sub-holes 1031, so that, on the premise of ensuring recording performance of the MEMS microphone, the airflow is dispersed into a plurality of parts when entering the back cavity, further reducing the impact of the air pressure on the diaphragm 31.

Further, in a thickness direction of the substrate 1, orthographic projections of the first sound inlet hole 102 and the second sound inlet hole 103 do not overlap. Due to staggered arrangement of the first sound inlet hole 102 and the second sound inlet hole 103, the airflow entering through the first sound inlet hole 102 may be blocked by a cavity wall of the buffering cavity 101 and then flow laterally along the buffering cavity 101 to the second sound inlet hole 103, which can further improve the buffering effect.

Further, referring to FIG. 1, in the thickness direction of the substrate 1, the orthographic projection of the first sound inlet hole 102 is located outside the back cavity. In this way, the sound inlet channel 10 composed of the first sound inlet hole 102, the buffering cavity 101, and the second sound inlet hole 103 is similar to a “Z”-shaped pipe. When the airflow enters, an impact force may be greatly reduced after being buffered by the “Z”-shaped pipe, thereby effectively buffering the impact force of the air pressure on the diaphragm 31 and ensuring operational reliability of the diaphragm 31.

Further, referring to FIG. 2, in the thickness direction of the substrate 1, the orthographic projection of the first sound inlet hole 102 is located in the back cavity. In the orthographic projections in the thickness direction of the substrate 1, each of the sub-holes 1031 surrounds an outer periphery of the first sound inlet hole 102. Optionally, the sub-holes 1031 are symmetrically arranged on two sides of the first sound inlet hole 102 in pairs, that is, an even number of sub-holes 1031 are provided and arranged in a circular array. In this way, the sound inlet channel 10 composed of the first sound inlet hole 102, the buffering cavity 101, and the second sound inlet hole 103 is similar to a “Y”-shaped pipe. The airflow, when entering and passing through the “Y” shaped pipe, first hits a region defined by the sub-holes 1031, and then disperses and flows to the sub-holes 1031. In this case, an impact force of the airflow flowing from the sub-holes 1031 to the back cavity is greatly reduced, thereby effectively buffering the impact force of the air pressure on the diaphragm 31 and ensuring operational reliability of the diaphragm 31. In some embodiments, an odd number of sub-holes 1031 are provided and arranged in a circular array.

Further, the substrate 1 includes a first substrate 11 enclosing the receiving space together with the housing 2 and a second substrate 12 fixed to a side of the first substrate 11 away from the housing 2, the first substrate 11 and the second substrate 12 are spaced apart to form the buffering cavity 101, the first sound inlet hole 102 is provided in the second substrate 12, and the second sound inlet hole 103 is provided in the first substrate 11. Both the MEMS chip 3 and the ASIC chip 4 are fixed to the first substrate 11, the MEMS chip 3 and the ASIC chip 4 may be electrically connected through a gold wire or through a printed circuit on the first substrate 11, and the ASIC chip 4 may be electrically connected to the first substrate 11 through a gold wire or directly electrically connected to the printed circuit on the first substrate 11.

Further, the substrate 1 further includes a fixing member 13 fixed between the first substrate 11 and the second substrate 12. The first substrate 11, the second substrate 12, and the fixing member 13 jointly enclose the buffering cavity 101. The first substrate 11 and the fixing member 13 may be connected by adhesion, and the second substrate 12 and the fixing member 13 may also be connected by adhesion. The buffering cavity 101 may be in a shape of a cube, a cylinder, or the like. The substrate 1 is composed of the first substrate 11, the second substrate 12, and the fixing member 13, which may make a manufacturing process simpler. In some embodiments, the substrate 1 may alternatively have a one-piece structure, and the buffering cavity 101 therein may be formed by removing an internal material of the substrate 1. In some embodiments, in order to further improve the buffering effect of the buffering cavity 101, the buffering cavity 101 may also be filled with a buffering material. The buffering material is optionally a soft porous material.

Further, the buffering cavity 101 faces the receiving space, and a junction between the housing 2 and the first substrate 11 faces the fixing member 13. In this way, reliability of the connection between the housing 2 and the substrate 1 can be ensured, and the substrate 1 has no cavity in a peripheral region of the housing 2. The substrate 1 has higher structural strength and is not easily damaged.

The above describes merely embodiments of the present disclosure. It should be pointed out herein that, for those skilled in the art, improvements can be made without departing from the creative concept of the present disclosure, all of which fall within the protection scope of the present disclosure.

What is claimed is:

1. A micro-electro-mechanical system (MEMS) microphone, comprising:
a substrate;
a housing enclosing a receiving space together with the substrate;
a MEMS chip enclosing a back cavity together with the substrate; and
an application specific integrated circuit (ASIC) chip fixed to the substrate,
wherein the substrate is provided with a sound inlet channel communicating the receiving space with the outside, and the MEMS chip comprises a diaphragm located on a sound inlet path of the sound inlet channel,
wherein the sound inlet channel comprises a buffering cavity located in the substrate, a first sound inlet hole provided in the substrate and communicating the buffering cavity with the outside, and a second sound inlet hole provided in the substrate and communicating the buffering cavity with the back cavity, and
wherein the second sound inlet hole comprises at least two sub-holes spaced apart from one another.

2. The MEMS microphone as described in claim 1, wherein a sum of cross-sectional areas of the sub-holes is smaller than 30% of a cross-sectional area of the first sound inlet hole.

3. The MEMS microphone as described in claim 1, wherein, in a thickness direction of the substrate, orthographic projections of the first sound inlet hole and the second sound inlet hole do not overlap with each other.

4. The MEMS microphone as described in claim 3, wherein, in the thickness direction of the substrate, the orthographic projection of the first sound inlet hole is located outside the back cavity.

5. The MEMS microphone as described in claim 3, wherein, in the thickness direction of the substrate, the orthographic projection of the first sound inlet hole is located in the back cavity.

6. The MEMS microphone as described in claim 5, wherein, in the thickness direction of the substrate, the orthographic projections of the at least two sub-holes are encircled on an outer periphery of the orthographic projection of the first sound inlet hole.

7. The MEMS microphone as described in claim 1, wherein the substrate comprises: a first substrate enclosing the receiving space together with the housing; and a second substrate fixed to a side of the first substrate away from the housing;
wherein the first substrate and the second substrate are spaced apart to form the buffering cavity, the first sound inlet hole is provided in the second substrate, and the second sound inlet hole is provided in the first substrate.

8. The MEMS microphone as described in claim 7, wherein the substrate further comprises a fixing member fixed between the first substrate and the second substrate, and
the first substrate, the second substrate, and the fixing member jointly enclose the buffering cavity.

9. The MEMS microphone as described in claim 8, wherein the buffering cavity directly faces the receiving space, and a junction between the housing and the first substrate directly faces the fixing member.
